(19) United States
(12) Patent Application Publication
(10) Pub. No.: US 2015/0357480 A1
(43) Pub. Date: Dec. 10, 2015

(54) STABLE METAL-OXIDE THIN FILM TRANSISTOR AND METHOD OF MAKING

(71) Applicants: Gang Yu, Santa Barbara, CA (US); Chan-Long Shieh, Paradise Valley, AZ (US); Tian Xiao, Santa Barbara, CA (US); Fatt Foong, Goleta, CA (US); Juergen Musulf, Santa Barbara, CA (US); Karl Birger Kristoffer Ottosson, Santa Barbara, CA (US)

(72) Inventors: Gang Yu, Santa Barbara, CA (US); Chan-Long Shieh, Paradise Valley, AZ (US); Tian Xiao, Santa Barbara, CA (US); Fatt Foong, Goleta, CA (US); Juergen Musulf, Santa Barbara, CA (US); Karl Birger Kristoffer Ottosson, Santa Barbara, CA (US)

(21) Appl. No.: 14/829,812

(22) Filed: Aug. 19, 2015

Related U.S. Application Data
(63) Continuation-in-part of application No. 12/206,615, filed on Sep. 8, 2008.

(51) Int. Cl. H01L 29/786; H01L 21/28; H01L 29/49; H01L 29/66; H01L 29/417; H01L 29/423; H01L 21/283; H01L 21/324

(52) U.S. Cl. CPC H01L 29/78693; H01L 21/283; H01L 21/28008; H01L 21/324; H01L 29/66742; H01L 29/41733; H01L 29/42384; H01L 29/42364; H01L 29/4908; H01L 29/78603

(57) ABSTRACT

A thin film semiconductor device has a semiconductor layer including a composite/blend/mixture of an amorphous/nanocrystalline semiconductor ionic metal oxide and an amorphous/nanocrystalline non-semiconducting covalent metal oxide. A pair of terminals is positioned in communication with the semiconductor layer and define a semiconductive channel, and agate terminal is positioned in communication with the semiconductive channel and further positioned to control conduction of the channel. The invention further includes a method of depositing the mixture including using nitrogen during the deposition process to control the carrier concentration in the resulting semiconductor layer.

### CROSS-REFERENCE TO RELATED APPLICATIONS

This application is a continuation-in-part application of currently pending U.S. application Ser. No. 12/206,615, filed Sep. 8, 2008.

### FIELD OF THE INVENTION

This invention relates to metal oxide semiconductor material for use in channel layers of semiconductor devices, especially in the back channel etch (BCE) type of thin film transistor (TFT) devices.

### BACKGROUND OF THE INVENTION

In thin film semiconductor devices such as thin film transistors (TFTs), the devices include spaced apart source and drain areas that conduct through a channel layer positioned therebetween. At least one gate insulator and gate electrode are positioned above and/or below the channel layer, to control the conduction. In many applications TFTs are used where high heat cannot be tolerated during fabrication and, thus, a semiconductor must be used that can be deposited at relatively low temperatures (e.g. room temperature) but which still has relatively high mobility and with sufficient operation stability.

There is a strong interest in metal oxide semiconductor because of its high carrier mobility, light transparency and low deposition temperature. The high carrier mobility expands applications to higher performance domains that require higher frequency or higher current. The light transparency eliminates the need for a light shield in display and sensor active matrices. The low deposition temperature enables application to flexible electronics on plastic substrates.

The unique features of metal oxide semiconductors are: (1) carrier mobility is less dependent on grain size of films, that is, high mobility amorphous or nanocrystalline metal oxide is possible; (2) density of surface states is low and enables easy field effect for TFTs, this is contrary to covalent semiconductors (such as Si or a-Si) where surface states have to be passivated by hydrogen; and (3) mobility strongly depends on the volume carrier density. In order to achieve high mobility for high performance applications, the volume carrier density of the metal oxide channel should be high and thickness of the metal oxide film should be small (e.g. <100 nm and preferably <50 nm).

However, a major deficiency of metal oxide semiconductors is stability and the tendency to become polycrystalline at higher temperatures. Popular metal oxides, such as zinc oxide, indium oxide, tin-oxide, gallium oxide and composite/blend made of their combinations such as indium tin oxide, indium zinc oxide, indium gallium zinc oxide, are not very stable and become polycrystalline at moderate temperatures (i.e. greater than approximately 400° C.). Polycrystalline semiconductor metal oxides with large crystalline grains (e.g., approaching micron grain size) are not desirable in semiconductor devices for several reasons. For example, the characteristics of transistors formed in polycrystalline semiconductor metal oxides can vary, even between adjacent devices in an array, because of the variation in crystal size and position. To better understand this problem, in a conduction area under a sub-micron gate each different transistor can include from one or two poly-silicon crystalline grains to several crystalline grains and the different number of crystals in the conduction area will produce different characteristics. The dimensions and their physical characteristics among different grains are also different. Another reason for favoring thin amorphous/nanocrystalline semiconductor layer is its robustness to mechanical bending. Such amorphous/nanocrystalline film is ideal semiconductor material for flexible electronic devices.

The stability of metal oxide thin film transistors (TFTs) depends strongly on processing temperatures. For TFT processed at high temperatures, the traps in the bulk semiconductor layer and at the interface or interfaces between the gate insulator and the semiconductor layer and/or between the passivation layer and the semiconductor layer can be reduced. For applications such as active matrix organic light emitting devices (AMOLED) extreme stability is required. It is advantageous to take the metal oxide TFTs to high temperatures, generally between 250° C. and 700° C., during processing. Meanwhile it is desirable to maintain the amorphous/nanocrystalline nature of the metal oxide at these processing temperatures.

The performance and stability of metal oxide TFTs also strongly depends on their structures and processing conditions. Generally, etch-stop type of TFTs have better stability than the BCE type of TFTs due to the fact that the former structure offers protection of the metal oxide channel during etching of source/drain metal, resulting in less damage to the top surface of the channel layer. However, the BCE type of TFTs are favored from the point of view of manufacturing efficiency and cost, due to one less deposition/patterning cycle. Therefore, there is currently a dilemma or trade-off between the selection of etch-stop type or BCE type of metal-oxide TFTs for manufacturing.

Further, the stability of metal oxide TFTs also strongly depends on the material and processing condition used for depositing gate insulator and source/drain metal. From the point of view of manufacturing efficiency and throughput, silicon nitride (SiNₓ) processed by PECVD is preferred as the gate insulator. However hydrogen content is usually very high when SiNₓ is deposited with the existing PECVD tools at the display manufacturing lines (for such SiNₓ, it is sometimes denoted as SiNₓ:H). The diffusion of hydrogen from the gate insulator into the metal oxide channel usually causes serious deterioration of the TFT stability. By choosing silicon oxide (SiOₓ), or SiONₓ as gate insulator material, the TFT stability can usually be improved, but the production efficiency is significantly decreased due to much longer time required for SiOₓ or SiONₓ deposition. Additionally, since the gate insulator layer made by PECVD SiOₓ or SiONₓ is more porous than SiNₓ, additional problems arise when copper is used as gate metal in applications requiring large-size and high resolution displays. Basically, copper will more easily diffuse through the SiOₓ or SiONₓ gate insulator into the metal oxide channel, deteriorating TFT stability. Similar deterioration of TFT stability due to copper diffusion into the metal oxide channel also occurs when copper is used in the source/drain metal (or stack of metals).

It would be highly advantageous, therefore, to remedy the foregoing and other deficiencies inherent in the prior art.

Accordingly, it is an object of the present invention to provide a new and improved metal oxide semiconductor material for a TFT channel layer.

Another object of the invention is to provide a new and improved metal oxide semiconductor material with improved stability and has less tendency to become polycrystalline at process temperatures required for high stability.

Another object of the invention is to provide a new and improved metal oxide semiconductor material with improved stability, high carrier mobility, and good control of oxygen vacancies.

Another object of the invention is to provide a new and more robust metal oxide semiconductor such that it can withstand the process damage associated with the back channel etch (BCE) process (either dry etch or wet etch of source/drain).

Another objective of the invention is to provide a new and improved metal-oxide TFT with less process steps, which are compatible with process tools well-established in a-Si TFT manufacture line.

Another object of the invention is to provide a new and more robust metal oxide semiconductor such that it is less susceptible to the deleterious effects of hydrogen diffusion from the gate insulator (GI) or copper diffusion from the gate metal or source/drain metal, into the channel region, thereby greatly improving the stability of the TFT.

Another object of the invention is to provide a stable thin film transistor and thin film circuit comprising such with the channel layer made of such stable metal oxide semiconductor channel.

### SUMMARY OF THE INVENTION

Briefly, to achieve the desired objects of the instant invention in accordance with a preferred embodiment thereof, a stable amorphous/nanocrystalline metal oxide material is provided for use as a semiconductor in semiconductor devices, the material includes a composite/mixture of an amorphous/nanocrystalline semiconductor ionic metal oxide and an amorphous/nanocrystalline non-semiconducting covalent metal/non-metal oxide. The stable amorphous/nanocrystalline metal oxide material is represented by one of the formula XOₐYO_{b}, and X—O—Y, where YO is an amorphous/nanocrystalline insulating covalent metal/non-metal oxide and XO is an amorphous/nanocrystalline semiconductor ionic metal oxide. The covalent metal/non-metal oxide, YO, tends to be amorphous/nanocrystalline and insulating when formed in its single phase. The ionic metal oxide, XO, tends to be polycrystallized with grain size of micron scale at process temperature and behaves as a semiconductor with energy gap larger than 2 eV when formed in its single phase. Adding YO into the composite/blend of XOₐYO_{b} prevents XO from polycrystallizing into micron size grains and results in amorphous/nanocrystalline semiconductor composite/blend film during film forming and following process steps, and thus results in a stable electronic device during storage and operation.

The desired objects of the instant invention are further achieved in a thin film semiconductor device having a semiconductor layer including a composite/mixture of an amorphous/nanocrystalline semiconductor ionic metal oxide and an amorphous/nanocrystalline non-semiconducting covalent metal/non-metal oxide. A pair of terminals is positioned in communication with the semiconductor layer and defines a conductive channel, and a gate terminal is positioned in communication with the conductive channel and further positioned to control conduction of the channel.

The invention further includes a method of fabricating metal oxide thin film transistors with a back channel etch (BCE) process by exploiting the chemically-robust (S/D etch-resistant) nature of the metal oxide channel made by blending/mixing a semiconductor ionic metal oxide with an amorphous/nanocrystalline non-semiconducting covalent metal/non-metal oxide. Also included in the method is a post-BCE passivation process and structure which enables effective protection of the channel from ambient moisture and light through use of multi-layers (including inorganic/inorganic, organic/organic or organic/inorganic combinations) which inhibit moisture accumulation and shield light.

The invention further includes a method of fabricating metal oxide thin film transistors with high process-throughput SiNₓ gate insulator, by exploiting the chemically-robust (hydrogen resistant) nature of the metal oxide channel made by blending/mixing a semiconductor ionic metal oxide with an amorphous/nanocrystalline non-semiconducting covalent metal/non-metal oxide.

The invention further includes a method of fabricating metal oxide thin film transistors compatible with copper-containing electrodes either as a gate terminal or as source/drain terminals, by exploiting the chemically-robust (copper resistant) nature of the metal oxide channel made by mixing a semiconductor ionic metal oxide with an amorphous/nanocrystalline non-semiconducting covalent metal/non-metal oxide.

### BRIEF DESCRIPTION OF THE DRAWING

The foregoing and further and more specific objects and advantages of the instant invention Will become readily apparent to those skilled in the art from the following detailed description of a preferred embodiment thereof taken in conjunction with the drawings, in Which:

FIG. 1 is a simplified layer diagram of a TFT in accordance with the present invention with overlying gate and underlying source/drain;

FIG. 2 is a simplified layer diagram of a TFT in accordance with the present invention with overlying gate and overlying source/drain;

FIG. 3 is a simplified layer diagram of a TFT in accordance with the present invention with underlying gate and underlying source/drain;

FIG. 4 is a simplified layer diagram of a TFT in accordance with the present invention with underlying gate and overlying source/drain;

FIGS. 5A and 5B show two simplified layer diagrams of back-channel etching type of TFTs with passivation layers;

FIG. 6 shows a Id-Vgs data set of a BCE TFT with XOₐYO_{b} channel layer; and

FIG. 7 shows uniformity of Id-Vgs from BCE MOTFT over a Gen-2.5 glass (370 mm×470 mm).

### DETAILED DESCRIPTION OF A PREFERRED EMBODIMENT

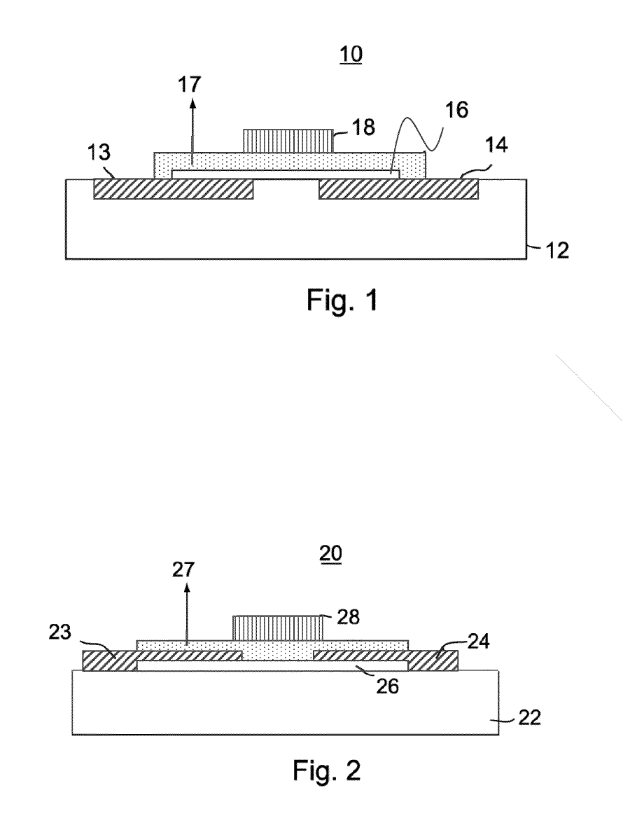

Turning now to FIG. 1, a simplified layer diagram of one embodiment of a TFT 10, in accordance with the present invention, is illustrated. TFT 10 includes a substrate 12, which may be a flexible material, such as plastic, stainless-steel, or any other convenient material, such as glass, etc. A source 13 and a drain 14 are formed in or on (hereinafter generically referred to as “on”) the upper surface of substrate 12 in a spaced apart orientation using any well-known method. A metal oxide semiconductor film 16 is formed in partial overlying relationship to both source 13 and drain 14 and the space therebetween. It will be understood that metal oxide semiconductor film 16 is the active layer that conducts carriers between the source/drain components. In a preferred embodiment, metal oxide layer 16 is less than 100 nm thick and preferably less than 50 nm. A thin gate dielectric layer 17 is formed in overlying relationship to metal oxide film 16 and a gate stack 18 is positioned on gate dielectric layer 17 in overlying relationship to the space between source 13 and drain 14. Thus, TFT 10 is a top gate, bottom source/drain type of device.

Turning now to FIG. 2, a simplified layer diagram of another embodiment of a TFT 20, in accordance with the present invention, is illustrated. TFT 20 includes a substrate 22, which may be a flexible material, such as plastic, stainless steel, or any other convenient material, such as glass, etc. A metal oxide semiconductor film 26 is deposited and patterned on substrate 22 and a source 23 and a drain 24 are formed partially in overlying relationship on the upper surface of metal oxide semiconductor film 26 so as to form a spaced apart orientation on the upper surface. A thin gate dielectric layer 27 is formed in overlying relationship to metal oxide semiconductor film 26 in the space between source 23 and drain 24 and to portions of source 23 and drain 24 adjacent to the space. A gate stack 28 is positioned on gate dielectric layer 27 in overlying relationship to the space between source 23 and drain 24. Thus, TFT 20 is a top gate, top source/drain type of device.

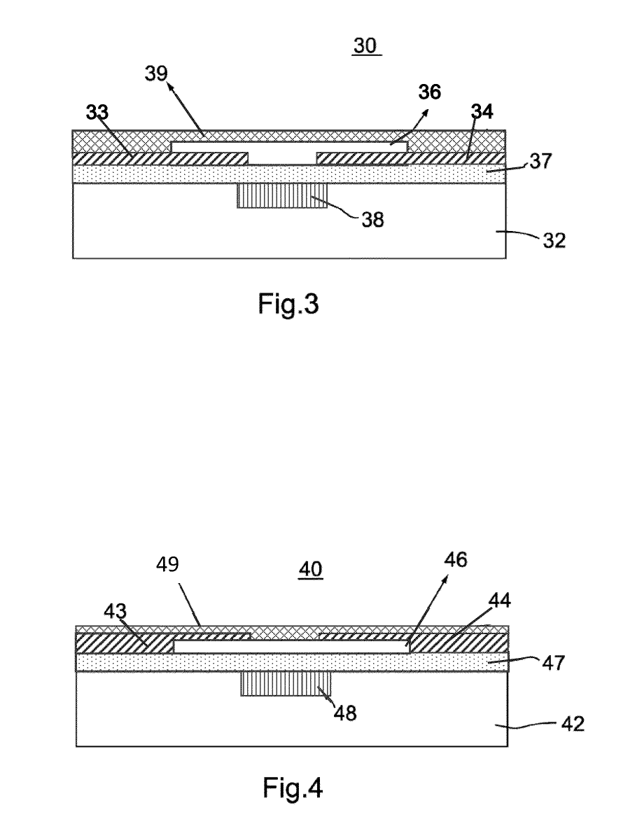

Turning now to FIG. 3, a simplified layer diagram of another embodiment of a TFT 30, in accordance with the present invention, is illustrated. TFT 30 includes a substrate 32, which may be a flexible material, such as plastic, stainless-steel, or any other convenient material, such as glass, etc. A gate stack 38 is formed in substrate 32 by any convenient and established method. A thin gate dielectric layer 37 is formed in overlying relationship to gate stack 38 and the surrounding areas of substrate 32. A source 33 and a drain 34 are formed in or on (hereinafter generically referred to as “on”) the upper surface of gate dielectric layer 37 in a spaced apart orientation using any well-known method. A metal oxide film 36 is formed in partial overlying relationship to both source 33 and drain 34 and the space therebetween. An optional passivation layer 39 is formed over metal oxide film 36 and part of the source 33 and drain 34. Thus, TFT 30 is a bottom gate, bottom source/drain type of device.

Turning now to FIG. 4, a simplified layer diagram of another embodiment of a TFT 40, in accordance with the present invention, is illustrated. TFT 40 includes a substrate 42, which may be a flexible material, such as plastic, stainless steel, or any other convenient material, such as glass, etc. A gate stack 48 is formed in substrate 42 by any convenient and established method. A thin gate dielectric layer 47 is formed in overlying relationship to gate stack 48 and the surrounding areas of substrate 42. A metal oxide film 46 is formed on gate dielectric layer 47 in overlying relationship to gate stack 48 and the surrounding area. A source 43 and a drain 44 are formed partially in overlying relationship on the upper surface of metal oxide film 46 so as to define a space therebetween on the upper surface overlying gate stack 48. An optional passivation layer 49 is formed over the exposed portion of metal oxide film 46 and the surrounding portions of source 43 and drain 44. Thus, TFT 40 is a bottom gate, top source/drain type of device.

It will be understood that the above four examples of thin film transistors illustrate only some of the possible embodiments. For example, each of the above examples is a single gate transistor. Double gate transistors, i.e. a gate above and below the channel, are known in conjunction with virtually all of the examples. It is intended that the present invention applies to all possible or potential thin film transistors and other thin film devices, e. g. diodes, etc. Further, for purposes of this disclosure it will be understood that in all of the TFT examples the metal oxide film is designed as being “deposited on the substrate”, even if a film is interposed therebetween.

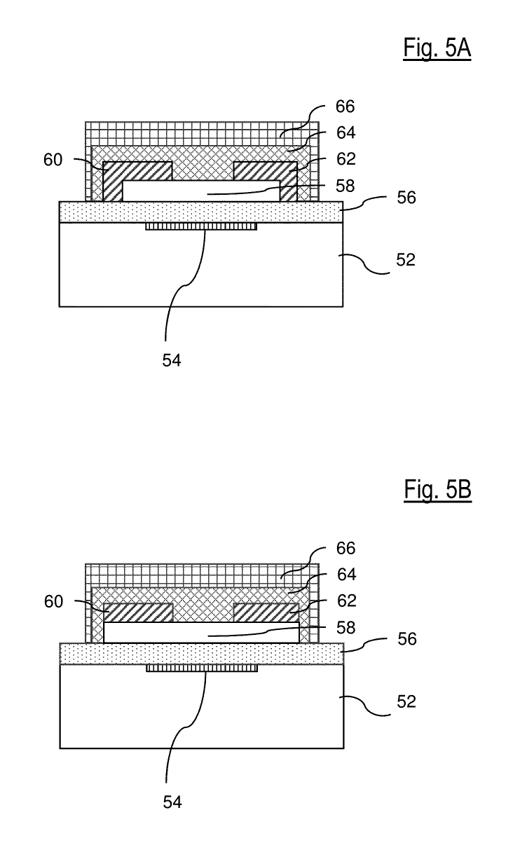

An alternative name for the TFT structure shown in FIG. 4 has been given as back-channel-etch (BCE) type TFT. Two variations of BCE type TFT with passivation layer(s) are also shown in FIGS. 5A and 5B. In these structures, a conductive gate layer 54 is deposited and patterned on the substrate 52, followed by deposition of gate dielectric (also called gate insulator) layer 56 over the gate layer 54 and the substrate 52. A layer 58 of semiconductor metal-oxide material is positioned on the gate dielectric layer 56 and forms a semiconductive channel between a pair of electrode terminals: a source electrode 60 and a drain electrode 62. Both of them are in contact with the semiconductor layer 58. A first passivation layer 64 and an optional second passivation layer 66 are then deposited to cover the semiconductor layer 58, the source 60 and the drain 62. In a preferred embodiment, the first passivation layer 64 is an inorganic dielectric material such as oxide or oxynitride with good adhesion with the semiconductor layer 58 and the source/drain 60 and 62 underneath. The passivation layers 64 and 66 could be formed by PVD (such as sputter, e-beam, or reactive thermos deposition), CVD, PECVD or MOCVD. Inorganic dielectric passivation layer 64 can also be formed from coating with a precursor solution or sol-gel along with a post coating annealing process in an ambient comprising oxygen and/or nitrogen. In addition to silicon based oxide or oxynitride, insulating metal-oxides, metal-oxynitrides (such as TiO2, Ta2O5, HfO2, ZrO2) can also be used. In another preferred embodiment, first passivation layer 64 is an organic or organo-metallic dielectric layer which can be formed by a coating or printing method. Inorganic/organic insulating dielectric layers formed with solution or sol-gel methods generally produce less damage to the channel top surface during fabrication (in contrast to PECVD and MOCVD), and thus retain better TFT performance. These passivation layer forming methods with solutions or sol-gels are also favored for cost reduction.

When passivation layer 64 is made of inorganic dielectric material, an optional second passivation layer 66 can be added thereover. A dense and/or hydrophobic layer 66 can inhibit moisture in the ambient from penetrating through the passivation layers 66 and 64 to reach the channel 58. Layer 66 can be either an inorganic material such as silicon oxide, silicon nitride or an organic material such as PMMA based polymer, PMGI, polyimide, polysiloxane, or other commercially available insulator polymers, insulting organometallic molecules (such as organo-alumina, organo-tantania, organo-titania, organo-hafnia, organo-zerconia), photoresists, liquid glasses and so on used as planarization layer or bank layer. Photopatternable organic materials and photoresists are preferred when via-holes or other patterns are need for layers 64 and 66.

Layer 66 can also be a class of material categorized as surface-assembled-monolayer (SAM) of organic molecules. One-side of SAM molecules has strong affinity to the passivation layer 64 underneath, the other side of SAM molecules has high hydrophobicity and repulsing to water molecules from the ambient. A multiple layer passivation layer can be achieved with multiple coatings, a process similar to that for a Langmuir-Blodgett film known to experts in the field.

Another class of organic materials called surface promoters (or adhesion promoters) or surface modifiers can also be used in layer 66 and layer 64. Such organic or organometallic molecules are characterized with a saturated carbon chain with one end-group with hydrophobic property and the other side with hydrophilic property. When coating over a metal-oxide channel, the surface promoters passivate the metal-oxide channel with a dense, thin layer with the top surface repulsing moisture in the ambient. Examples of silane-based surface promotors include hexamethyldisilazane (HMDS), and diphenylsilanediol-derivatives (AR 300-80). The former is often processed with a spray coater, or vapor-primer and the later is often processed with a spin-coater, slit coater or slot coater. Examples of organometallic molecule based surface promotors/modifiers include organo-titanium molecules. Such thin films can be formed by a sol-gel or a solution processed by casting, spin-coating, slot-coating, or one of printing methods known to the experts in the arts. Hydrogen and Carbon groups in such organo-metallic molecules can be removed partially or completely with a post-casting annealing process. In the case of hydrogen/carbon full removal, a thin, dense metal-oxide passivation film is formed without damage to the channel layer underneath. An example of forming such a surface modifier layer between photosensing layer and cathode in a photovoltaic cell has been described in Advanced Material, Vol 18, pp 572-576 (2006).

When an organic layer is used for passivation layer 64, an inorganic passivation material (for example, as described for passivation layer 64 above) can be used for optional passivation layer 66.

Combinations of the organic materials described above can also be used for passivation layers 64 and 66 in either stack or blend forms. The thickness of each passivation layer(s) in 64 and 66 can range from a few molecular layer (˜nm) to a few microns. The total thickness of passivation layers 64 and 66 is typically no more than 5 microns.

No matter which passivation material and process is selected, it is preferred to keep the top free-surface of the passivation layer 64 (or 66 when a bi-layer passivation structure is used) hydrophobic. This can be done with a coating process with SAM or surface promotor material, or with a plasma surface treatment with a fluorine based gas (such as CF4 or SF6).

The difference between TFT 50A and TFT 50B is the relative dimensions between the channel layer 58 and the source/drain layer 60/62. In TFT 50A, the channel layer and the outer dimensions of the source/drain layer are different, which are typically made from two mask steps. While in 50B, the outer dimensions of the channel and the source/drain layer are kept the same. Such structure can be achieved with a single photomask step with a half-tone photo-exposure process known to experts in the field. Processes of active matrix liquid crystal display backpanels based on TFT 50A typically involve five mask steps. In contrast, processes of active matrix liquid crystal display backpanels based on TFT 50B typically involve four mask steps. In applications sensitive to process cost, processes related to TFT 50B are preferred. Also in general, less mask process steps also results in better process yield. In addition, when sputter is used for both channel layer (58) and source/drain layer (60, 62), the process for fabricating TFT 50B enables continuous deposition of the metal layer of source 60 and drain 62 over metal oxide semiconductor channel layer 58 without a vacuum break, ensuring a clean interface and superb contact quality between metal oxide semiconductor layer 58 and source 60 and drain 62.

Amorphous/nanocrystalline metal oxide semiconductor materials are desirable for use in the channel layer of semiconductor devices because of their high carrier mobility and device uniformity. They also enable large size, foldable electronic devices due to its superb sustainability under bending. However, metal oxide semiconductors, such as zinc oxide, indium oxide, tin oxide, gallium oxide and combinations thereof, are relatively unstable and have a tendency to become polycrystalline at higher process temperatures. Polycrystalline semiconductor metal oxides are not desirable in semiconductor devices because of the many drawbacks in their structure.

It is known in the art that the channel length of presently standard thin film transistors is less than approximately 5 microns. For purposes of this disclosure the term “amorphous, nanocrystalline, or amorphous/nanocrystalline” is defined as a material with grain size, along the channel length, much less than the channel length of presently standard thin film transistors, e.g. approximately 100 nanometers or less.

Some amorphous/nanocrystalline metal or non-metal oxides, such as aluminum oxide, boron oxide, silicon oxide, magnesium oxide, beryllium oxide, and composites comprising combinations thereof, are very stable and do not become polycrystalline easily at the process temperatures. However, these metal/non-metal oxides are not good semiconductors and cannot be used as the channel layer in semiconductor devices in their normal state.

It has been found that the stability of amorphous/nanocrystalline metal oxide semiconductor materials can be greatly improved by blending/mixing some non-semiconducting amorphous or nanocrystalline metal/non-metal oxides with the ionic metal oxide semiconductor materials. The component of non-semiconducting amorphous/nanocrystalline metal/non-metal oxide prevents the component of ionic metal oxide semiconductor from becoming polycrystalline with large grain sizes, resulting in amorphous/nanocrystalline semiconductor composites/blends/mixtures with all phases and components in amorphous/nanocrystalline structure. In the case of mixtures with multiple phases, because the non-semiconducting amorphous or nanocrystalline metal oxides are virtually non-conducting, it is necessary to provide a continuous network of the amorphous or nanocrystalline metal oxide semiconductor materials through the resulting mixture. Thus, carrier flow is not interrupted by the non-semiconducting amorphous/nanocrystalline metal oxide material mixed with the ionic amorphous/nanocrystalline metal oxide semiconductor materials and mobility of the composite oxide can be high. Thus, the stability of the composite oxides is enhanced by the stable oxide component but the mobility remains high. Further, it will be understood that several different types of non-semiconducting amorphous/nanocrystalline metal oxides with different valences or other characteristics may be included in a composite mixture to achieve different results, at least one result being enhanced stability.

Some typical non-semiconducting amorphous/nanocrystalline metal oxides that can be used in a composite mixture include AlO, SiO, MgO, BeO, BO, and the like, and combinations thereof. In the technical literature, SiO and BO are sometimes called non-metal oxides. Generally, the non-semiconducting amorphous/nanocrystalline metal/non-metal oxides are more covalent in nature with a relatively high energy gap, that is E_{g} greater than approximately 6 eV. For ease of understanding, the non-semiconducting amorphous/nanocrystalline metal/non-metal oxides may be referred to generically as ‘covalent metal/non-metal oxides’.

Some typical metal oxide semiconductor materials include zinc oxide, indium oxide, tin oxide, gallium oxide, cadmium oxide, tantalum oxide, titanium oxide, tungsten oxide, molybdenum oxide, vanadium oxide, niobium oxide, and the like, and composite/blend/mixture comprising their combinations. Generally, the metal oxide semiconductor materials are more, or practically, ionic in nature with a relatively low energy gap, that is E_{g} less than approximately 4 eV. For ease of understanding, the semiconducting metal oxides may be referred to generically as ‘ionic metal oxides’. Many amorphous ionic metal oxide films formed at low temperature processes tend to become crystallized under a post annealing at high temperature or under storage at ambient conditions.

Different valence metals, i.e. metals from different groups in the periodic table, and mixtures thereof can be used to enhance stability or desirable semiconductor characteristics in a composite mixture. It will be understood that some covalent metal/non-metal oxides will add more stability because they have a greater tendency not to crystallize (e.g. a higher energy gap). Also, the amount of stable or covalent metal/non-metal oxide added to the composite mixture is determined by the necessity to maintain a continuous network of the amorphous or nanocrystalline metal oxide semiconductor materials.

In the present composite/blend/mixture, the amorphous/nanocrystalline metal oxide semiconductor components are represented by XO and the non-semiconducting amorphous/nanocrystalline metal oxide components are represented by YO. Thus, a formula for the composite/blend/mixture can be described as XOₐYO_{b}, where ‘a’ is the amount of amorphous/nanocrystalline metal oxide semiconductor material (ionic metal oxide) in the composite mixture and ‘b’ is the amount of non-semiconducting amorphous/nanocrystalline metal/non-metal oxide material (covalent metal/non-metal oxide) in the composite mixture. In this equation ‘a’ and ‘b’ can be used to describe molecular amount, weight amount, or number of metal-oxide bonds. It should be understood that ‘a’ and ‘b’ are non-zero (greater than zero) and to comply with the requirement that the composite mixture include a continuous network of the amorphous/nanocrystalline metal oxide semiconductor materials, ‘a’ will generally be larger than ‘b’. In certain circumstance, b is larger than a few %, e.g., larger than approximately 3% of the total material (a+b). Also, the amount of amorphous/nanocrystalline semiconductor ionic metal oxide is preferably greater than approximately 17% of the total mixture.

High temperature annealing of such mixture oxide (for example, in process of forming sputter target) often transfer the oxide mixture from multiple phases into a single phase alloy oxide composite/blend (sometimes also called a solid solution). Thin films formed from sputter deposition processes with such target retains such uniform, single phase morphology. One characteristic of such amorphous/nanocrystalline semiconductor oxide is a single oxygen atom bonded to both the metal corresponding to ionic semiconductor oxide X—O (XO) and the metal/non-metal oxide corresponding to covalent insulator oxide, Y—O (YO): i.e., forming X—O—Y bond structure at atomic (sub-nanometer) scale. The chemically stable O—Y bond helps stabilizing the ionic X—O bond and thus, improves the stability of the metal-oxide TFT under storage and during operation under biasing field.

The bonding dissociating energy of such covalent metal-oxide bond, O—Y (YO), is often larger than the ionic metal-oxide bond, X—O (XO), in the mixture/composite. The amorphous/nanocrystalline semiconductor metal oxide composites/blends/mixtures disclosed in this invention provide a new class of stable semiconductor metal-oxide which is of particular importance for electronic device and circuit applications.

One property change that arises from mixing a stable covalent metal oxide with an amorphous or nanocrystalline metal oxide semiconductor material is that the stable covalent metal oxide tends to reduce the number of oxygen vacancies. If oxygen is used during deposition in the normal procedure (i.e. less than 5%), the oxygen vacancies can be substantially reduced and the conduction (mobility) of the composite material can become too low. For example, it has been found that by using oxygen during the deposition, carriers are decreased to less than 10¹⁸ carriers per cm³. Thus, the use of oxygen to control the carrier concentration in the composite mixture, while it is possible, is a relatively sensitive process.

Instead of using oxygen to control the carrier concentration during deposition, it has been found that nitrogen (N₂) can be used to reduce the carrier concentration. The presence of N₂ during deposition can reduce the carrier concentration, but not as strongly as oxygen because nitrogen is less reactive compared to oxygen. Thus, the use of nitrogen is less sensitive and it is easier to achieve the desired carrier concentration.

In addition to using N₂ gas during deposition, it has also found that a post annealing under N₂, O₂ or mixture of both after TFT process steps (see FIG. 5) can improve TFT stability. Typical annealing temperature is in range of 150-400° C. Such process step is easy to be implemented in the manufacture line, for example, at a stage after completing active matrix backpanel production and before starting LCD or OLED process steps.

Thus, a new and improved metal oxide semiconductor material has been disclosed that has improved stability and has less tendency to become polycrystalline at higher temperatures. Also, the new and improved metal oxide semiconductor material has high carrier mobility and good control of oxygen vacancies.

The stable metal-oxide disclosed in this invention is ideal for use as the channel layer in a TFT. In one special case, it enables the production of a TFT with BCE structures shown in FIGS. 4 and 5. Because of the stronger bonding of oxygen to the metals, enabled by both “X—O” and “Y—O” bonds in the XOₐYO_{b} composite, the improved metal oxide semiconductor material enhances the chemical resistance of the channel to etching damage caused by wet or dry etching of the source/drain contacts in the back channel etch (BCE) process. It is ideal to adopt the source/drain metal materials popular in the existing a-Si TFT manufacture lines, such as Mo, Al, Cu, Ti, Nd, or their combinations in stack or in alloy forms. The metal-oxide semiconductor material, XOₐYO_{b} disclosed in this invention enables manufacturing of MOTFT in BCE type structures (FIG. 4 and FIG. 5) with conventional metal materials for the source and drain metal layer and with either dry-etching or wet-etching processes originally developed for a-Si TFT. A specific example is gate and/or source/drain metal layer(s) comprising Cu or Al, for applications requiring high conductivity. The stable channel layer is chemically resistant to copper or Al etchants during patterning of the source and drain layer. Such new and improved metal-oxide channel layer is also resistant to copper diffusion from either the gate metal or the source/drain metal, into the channel region during processing, storage and operation, thereby greatly improving the stability of the TFT. In addition, the improved metal oxide semiconductor channel material is less susceptible to the deleterious effects of hydrogen diffusion from the gate insulator (GI), layer 56 in FIG. 5, made with PECVD (such as SiNₓ:H and SiOₓ:H and their combinations in stack or in blend form). In addition to silicon-based nitride and oxide, there are also interests in making metal-oxide TFT with oxide dielectric with high dielectric constant (often called high K), example of such materials include Al₂O₃, HfO₂, ZrO₂ and alloy oxides comprising combinations of them. Typical processes and tools for forming such high dielectric constant layers include CVD, MOCVD, PECVD, atomic layer deposition (ALD), reactive sputter, anodization, plasma oxidation, thermal oxidation, coating with a precursor solution and with a following annealing in oxygen and/or nitrogen contained ambient. In contrast to vapor precursors used in CVD methods, coating with a precursor solution can be viewed as chemical-solution-deposition (CSD). One could also form the GI layer 56 with combinations of the materials mentioned above in either stack or in blend/composite forms. One feature in common for the gate dielectric films form by process methods above is that there is residue hydrogen existing in the forming film, either from the precursor chemical, or from gas residue during deposition. The improved metal oxide semiconductor material disclosed in this invention enables stable metal-oxide TFT with the GI comprising hydrogen.

The stable metal-oxide/metal oxide semiconductor channel is non-reactive to chemical exposures during source/drain metal layer deposition and patterning, non-reactive to the chemical exposures during passivation layer and other following layers, depositions and patterning. The stable metal oxide/metal oxide semiconductor channel layer is also resistant to hydrogen, Cu diffusion from abutting layers above and below during TFT storage and operation.

The stable metal-oxide/metal oxide TFT disclosed in this invention with structures shown in FIG. 1 to FIG. 5 can be used for constructing thin film circuits for a variety of applications, including active matrix liquid crystal displays, active matrix organic light displays, active matrix inorganic light emitting displays, active matrix electrophoretic displays, active matrix microelectromechanical-system (MEMS) displays, large size image arrays, radiation detector arrays, X-ray image arrays, chemical/biosensor arrays, pressure sensing arrays, touch panel arrays, proximity sensing arrays and electronic arrays with multiple functionality based on combinations of the above. In such thin film circuits, capacitors can be produced in combination with the gate dielectric layer with metals below and above, or with the passivation dielectric layer with metals below and above. Resistance can be constructed with a transistor with proper width and channel length and with the gate electrode connecting to either source or drain electrode.

With a third electrode layer, a TFT with double-gate (both top and bottom gates) can be constructed by combing FIG. 3 or FIG. 4 with FIG. 1 or FIG. 2. Such dual-gate metal-oxide TFT can add more functions in the space allowed for a single TFT, and thus are useful for high pixel density array designs.

In certain applications including AMLCD, it is preferable to optimize the metal-oxide TFT with both high carrier mobility under forward bias and stable performance under reverse gate-to-source/drain bias, both in dark and under light illumination. This could be achieved by tuning the channel composition in a vertical direction. For example, oxygen concentration can be varied vertically by properly annealing the channel in an oxygen rich or oxygen deficient environment.

A bilayer or multiple-layer stack can also be used for the channel with the layer in contact with source and drain with more YO than the layer contacting the gate insulator layer: i.e., ‘b’ is higher in the vicinity of channel-to-passivation interface than that in vicinity of channel-to-GI interface.

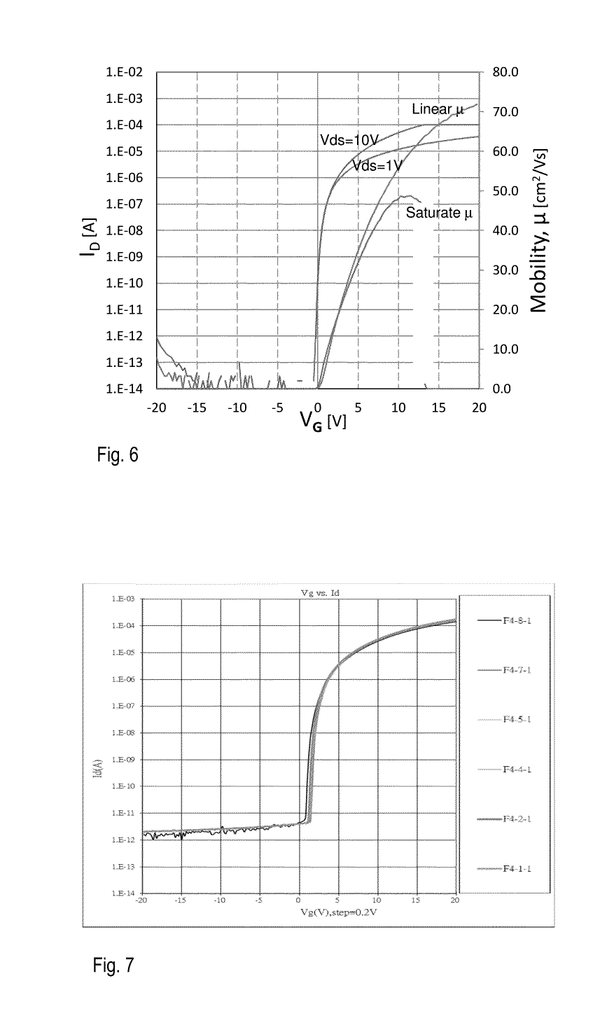

As an example, FIG. 6 shows a typical Id-Vgs curve from a TFT with channel layer in XOₐYO_{b} structure which was made with the BCE structure shown in FIG. 5A. In this case, YO near the passivation interface is more than 10 times of that near the GI interface. Source drain metal layers were made with the same material as those used in a-Si TFT line and were patterned with a wet etching process with commercial etchant. SiO₂ was used for passivation layer 64 and an organic layer was used as passivation layer 66. Channel width was 5 μm and channel length was 8 μm. The device shown has high “ON” current for Vgs>0 and low “OFF” current when Vgs<0. The current switching ratio was over 10¹⁰ at Vgs=+/−12V. Linear and saturate mobility's were 60 and 50 cm²/Vsec at Vgs=12V. This device has shown good stability under Vgs bias: <+/−0.1V for Vgs=+/−20V at 75° C. after 3600 seconds stress. This device also shows good operation stability under either light illumination or high operation current. No significant I-V change after passing charge through the channel equivalent to operating an OLED display over targeting lifetime. The stable channel enables one to use common metals for source and drain metal and wet etching process with commercial etchant for a-Si TFT manufacture lines. Moreover, the stable channel is also robust to chemical environment during SiO₂ passivation process by PECVD, indicated with uniform Id-Vgs over the substrate area. This is in contrast to uniformity issue frequently seen in MOTFT made with ZnO and InGaZnO.

FIG. 7 shows a group of Id-Vgs curves taken from a Gen-2.5 glass substrate over 370 mm×470 mm. The TFTs were made with the semiconductor metal-oxide channel in XOₐYO_{b} form in which Y=Al and X=In and Zn. In this experiment, a polyimide based photopatternable polymer layer was used as passivation layer 64. The top surface of the passivation layer has hydrophobic features and is resistant to water from attacking its surface. The variation of Vth (as defined by Vgs(max)−Vgs(min) at 1 nA level) is 0.5 V. These panels were produced by a manufacturing line with high manufacture throughput. A commercial Cu etchant was used for the source/drain etching process. The uniform TFT performance over the entire panel area demonstrates the chemical robustness of the XOₐYO_{b} channel to the commercial Cu etchant used for TFT industry.

In another application one could minimize charge trapping and TFT sensitivity to light exposure by adopting a XOₐYO_{b} channel layer with high YO concentrations near both GI and Passivation interface. In one special case, ‘b’ near channel-to-GI interface can be in range of 0<b<3%, and ‘b’ near channel-to-passivation interface can be substantially larger than 5% (in this description, percentage is defined by b/(a+b)). Such composite change along vertical direction can be achieved by several methods. For example, in the case of forming the channel layer with sputter deposition, the gradient composition change can be achieved by co-deposition with two sputter targets with a proper rate change. In the case of inline or cluster sputter tools in the manufacturing line, the ‘b’ composition change can be achieved by moving the substrate between different deposition zones with a corresponding ‘b’ composition change.

Another approach for arranging a stable XOₐYO_{b} channel layer is to take ionic semiconductor XO with two sub components X1-O and X2-O with the following formula: [(X1-O)ₐ₁(X2-O)ₐ₂]ₐYO_{b} (a=a1+a2, a+b=1) in which the chemical dissociation energy of X2-O bond is substantially higher than X1-O bond. In the channel layer with [ (X1-O)ₐ₁(X2-O)ₐ₂]ₐYO_{b} composite/mixture, one could vary the composition along the vertical direction in the channel layer. For example, the X2-O in the vicinity of channel-GI and channel-passivation interfaces is higher than in the center along the vertical direction. Stack layers can be produced without vac break so that improves channel layer quality is achieved.

Metal-oxide TFTs were also made with the structure and a process flow corresponding to FIG. 5B. Performance similar to that made follow FIG. 5A were achieved.

Various changes and modifications to the embodiment herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A method of forming a thin film semiconductor device with a stable metal-oxide channel layer, the method comprising the steps of:
selecting a substrate with dielectric top surface;
depositing a gate metal layer on the substrate and patterning the gate metal layer to a pre-determined pattern defining a gate electrode area;
depositing a gate dielectric layer overlying the gate electrode area;
forming a stable metal-oxide semiconductor active layer on the gate dielectric layer overlying at least the gate electrode area;
depositing a source/drain metal layer over the metal-oxide semiconductor active layer and patterning the source/drain metal layer to form source and drain terminals positioned in communication with the metal oxide semiconductor active layer and defining a conductive channel in the metal oxide semiconductor active layer;
depositing a first passivation layer over the conductive channel and at least part of source and drain terminals;
depositing an optional second passivation layer with a hydrophobic surface property; and
performing post-fabrication annealing; and
the stable semiconductor metal oxide channel layer including a composite/blend/mixture of an amorphous/nanocrystalline insulating covalent metal oxide material and an amorphous/nanocrystalline semiconductor ionic metal oxide material,
the composite/blend/mixture of the amorphous/nanocrystalline insulating covalent metal oxide material and the amorphous/nanocrystalline semiconductor ionic metal oxide material having a carrier concentration determined by one of oxygen and/or nitrogen being included during the deposition and/or after post-fabrication annealing.

2. A method as claimed in claim 1 wherein the steps of depositing and patterning the gate metal layer or the source/drain metal layer comprise depositing and patterning Mo, Al, Cu, Ti, Nd, or their combinations in stack or in alloy form.

3. A method as claimed in claim 1 wherein the step of depositing the gate dielectric layer with traceable hydrogen includes depositing SiNₓ:H, SiOₓ:H, SiONₓ:H, Al₂O₃, HfO₂, ZrO₂, or their combinations in stack or in composite/blend form by PECVD, atomic layer deposition, reactive sputter, anodization, plasma oxidation, thermal oxidation, coating with a precursor solution or a precursor sol-gel and with a following annealing in oxygen and/or nitrogen contained ambient.

4. A method as claimed in claim 1 wherein the step of depositing the first passivation layer includes depositing SiNₓ, SiOₓ, SiONₓ, Al₂O₃, HfO₂, ZrO₂, or their combinations in stack or in blend/composite forms.

5. A method as claimed in claim 4 wherein tool(s) used for depositing the first passivation layer include CVD, MOCVD, PECVD, atomic layer deposition, reactive sputter, anodization, plasma oxidation, thermal oxidation, coating with a precursor solution or a precursor sol-gel and with a following annealing in oxygen and/or nitrogen ambient.

6. A method as claimed in claim 1 wherein the steps of depositing the first passivation layer includes depositing a surface-assembled-monolayer (SAM), a surface promotor, a surface modifier, an organic/organometallic dielectric layer or their combination in stack or in blend form.

7. A method as claimed in claim 6 wherein the deposited organic/organometallic dielectric first passivation layer is photopatternable.

8. A method as claimed in claim 1 wherein the steps of depositing the optional second passivation layer include depositing SAM, surface promotors, surface modifier, and organic/organometallic films.

9. A method as claimed in claim 8 wherein the deposited organic/organometallic dielectric second passivation layer is photopatternable.

10. A method as claimed in claim 6 and claim 8 wherein tools used for depositing the first and optional second passivation layer include vapor-primer, spin-coater, spray coater, doctor blade coater, slot-coater, or one of printing tools.

11. A method as claimed in claim 1 wherein the steps of forming the semiconductor metal-oxide active channel layer includes sputter process with a sputter target comprising the stable XOₐYO_{b} mixture and X—O—Y bonds.

12. A method as claimed in claim 1 wherein the step of forming the semiconductor metal-oxide active channel layer includes a composite/blend/mixture in XOₐYO_{b} form which is chemically resistant to etchant used in source/drain patterning process.

13. A method as claimed in claim 1 wherein the step of forming the semiconductor metal-oxide active channel layer includes coating the metal-oxide channel film or a precursor film with a mixture solution comprising organo-metallic molecules and then anneal the precursor film in an environment comprising oxygen, and/or nitrogen.

14. A method as claimed in claim 1 wherein the step of forming the pattern of semiconductor metal-oxide active channel layer and the pattern of source/drain metal layer is performed with a single mask process.

15. A method as claimed in claim 14 wherein the single mask for forming the pattern of semiconductor metal-oxide active channel layer and the pattern of source/drain metal layer is a half-tone photo mask.

16. A method as claimed in claim 1 wherein the steps of depositing the semiconductor metal-oxide active channel layer and depositing source/drain metal layer are carried out in sequence without vacuum break.

17. A method as claimed in claim 1 wherein the steps of post-fabrication annealing is carried out in oxygen and/or nitrogen ambient with a pre-determined ratio in a temperature range of 150° C.-400° C.

18. A method of forming a thin film semiconductor device with a stable metal-oxide channel layer, the method comprising the steps of:
selecting a substrate with a dielectric top surface;
depositing a gate metal layer on the dielectric top surface of the substrate and patterning the gate metal layer to a pre-determined gate electrode area;
depositing a gate dielectric layer overlying the gate electrode area;
depositing a stable metal-oxide semiconductor active layer overlying at least the gate dielectric area, and a source/drain metal layer sequentially without vacuum break;
patterning the stable metal-oxide semiconductor active layer and the source/drain metal layer with a half-tone photo mask, the patterned source/drain metal layer defining source and drain electrode areas and a channel area in the semiconductor active layer;
depositing a first passivation layer over the channel area and at least part of source and drain electrode area;
depositing an optional second passivation layer with a hydrophobic surface property;
the stable semiconductor metal oxide channel layer including a composite/blend/mixture of an amorphous/nanocrystalline insulating covalent metal oxide material and an amorphous/nanocrystalline semiconductor ionic metal oxide material, and
the composite/blend/mixture of the amorphous/nanocrystalline insulating covalent metal oxide material and the amorphous/nanocrystalline semiconductor ionic metal oxide material having a carrier concentration determined by one of oxygen and/or nitrogen being included during the deposition and/or during post-fabrication annealing.

19. A method as claimed in claim 18 wherein the step of depositing the composite/blend/mixture of amorphous semiconductor ionic metal oxide and amorphous insulating covalent metal oxide includes depositing a mixture in which the an amorphous semiconductor ionic metal oxide includes one of zinc oxide, indium oxide, tin oxide, gallium oxide, cadmium oxide, tantalum oxide, titanium oxide, tungsten oxide, molybdenum oxide, vanadium oxide, niobium oxide, and combinations thereof.

20. A method as claimed in claim 18 wherein the step of depositing the mixture of amorphous semiconductor ionic metal oxide and amorphous insulating covalent metal oxide includes depositing a mixture in which the amorphous insulating covalent metal oxide includes one of aluminum oxide, silicon oxide, magnesium oxide, beryllium oxide, boron oxide, and combinations thereof.

21. A stable thin film semiconductor device comprising:
a substrate with dielectric top surface;
a gate metal layer on top of the substrate;
a gate dielectric layer overlying the gate electrode area;
a stable metal-oxide semiconductor active layer overlying the gate electrode area;
source/drain metal terminals positioned over the semiconductor active layer and in communication with the semiconductor active layer, the space between the source and drain terminals defines a conductive channel in the semiconductor active layer;
a first passivation layer over the conductive channel and at least part of the source/drain terminals;
an optional second passivation layer with hydrophobic surface property positioned in overlying relationship to the first passivation layer;
the stable semiconductor metal oxide channel layer including a composite/blend/mixture of an amorphous/nanocrystalline insulating covalent metal oxide material and an amorphous/nanocrystalline semiconductor ionic metal oxide material, and
the composite/blend/mixture of the amorphous/nanocrystalline insulating covalent metal oxide material and the amorphous/nanocrystalline semiconductor ionic metal oxide material having a carrier concentration determined by one of oxygen and/or nitrogen being included during the deposition and/or after post-fabrication annealing.

22. The thin film semiconductor device as claimed in claim 21 wherein the substrate is a glass, stainless steel or plastic sheet.

23. The thin film semiconductor device as claimed in claim 21 wherein the substrate is one of rigid or flexible.

24. The thin film semiconductor device as claimed in claim 21 wherein the stable semiconductor metal oxide material in the conductive channel has a grain size equal to or smaller than 100 nm.

25. The thin film semiconductor device as claimed in claim 21 wherein the gate metal layer or source/drain metal layer comprises Mo, Al, Cu, Ti, Nd, or their combinations in stack or in alloy blend.

26. The thin film semiconductor device as claimed in claim 21 wherein the gate dielectric layer comprises a traceable amount of hydrogen including SiNₓ:H, SiOₓ:H, SiONₓ:H, Al₂O₃, HfO₂, ZrO₂, or their combinations in stack or in composite/blend form.

27. The thin film semiconductor device as claimed in claim 21 wherein the first passivation layer includes one of SiN₂:H, SiO₂:H, SiON₂:H, Al₂O₃, HfO₂, ZrO₂, a surface-assembled-monolayer (SAM), a surface promotor layer, an organic dielectric layer or their combination in stack or in blend forms.

28. The thin film semiconductor device as claimed in claim 21 wherein the optional second passivation layer includes one of a surface-assembled-monolayer (SAM), a surface promotor layer, an organic dielectric layer or their combination in stack or in blend forms.

29. The thin film semiconductor device as claimed in claim 21 wherein the device is incorporated into thin film circuit applications including active matrix displays, image sensor array, touch sensor arrays, proximity sensing arrays, biosensor arrays, chemical sensor arrays and proximity sensing arrays and electronic arrays with multiple functionalities based on combinations above.

30. The thin film semiconductor device as claimed in claim 29 wherein the active matrix displays are active matrix liquid crystal displays, active matrix organic light emitting displays, active matrix inorganic light emitting displays, active matrix electrophoretic displays, and active matrix MEMS (microelectromechanical system) displays.

31. The thin film semiconductor device as claimed in claim 21 wherein the amorphous/nanocrystalline semiconductor ionic metal oxide in the mixture is in an amount much greater than the amorphous/nanocrystalline insulating covalent metal oxide.

32. The thin film semiconductor device as claimed in claim 21 wherein the amount of amorphous/nanocrystalline semiconductor ionic metal oxide in the mixture is greater than approximately 17% of the mixture.

33. The thin film semiconductor device as claimed in claim 21 wherein the amount of amorphous/nanocrystalline insulating covalent metal oxide is sufficient to prevent the amorphous/nanocrystalline semiconductor ionic metal oxide from becoming poly crystalline at processing temperatures in a range of approximately 250° C. to approximately 700° C.

34. The thin film semiconductor device as claimed in claim 21 wherein the amorphous/nanocrystalline insulating covalent metal oxide in the mixture is greater than approximately 3% of the mixture.

35. The thin film semiconductor device as claimed in claim 21 wherein the amorphous/nanocrystalline semiconductor ionic metal oxide includes one of zinc oxide, indium oxide, tin oxide, gallium oxide, cadmium oxide, tantalum oxide, titanium oxide, tungsten oxide, molybdenum oxide, vanadium oxide, niobium oxide, or combinations thereof.

36. The thin film semiconductor device as claimed in claim 21 wherein the amorphous/nanocrystalline insulating covalent metal oxide includes one of aluminum oxide, silicon oxide, magnesium oxide, beryllium oxide, boron oxide, or combinations thereof.

37. The thin film semiconductor device as claimed in claim 21 wherein the composite/blend/mixture is represented by the formula XOₐYO_{b}, where YO is an amorphous/nanocrystalline insulating covalent metal oxide and XO is an amorphous/nanocrystalline semiconductor ionic metal oxide and where ‘a’ is the amount of amorphous/nanocrystalline semiconductor ionic metal oxide in the composite/blend/mixture and ‘b’ is the amount of amorphous/nanocrystalline insulating covalent metal oxide in the composite mixture and where ‘a’ and ‘b’ are >0.

38. The thin film semiconductor device as claimed in claim 21 wherein the composite/blend/mixture comprises metal oxide bonds in the form of X—O—Y, wherein the oxygen atom is bonded with a metal/non-metal atom Y which is originated from the insulating covalent metal/non-metal oxide YO as well as bonded with a metal atom X which is originated from the semiconductor ionic metal oxide XO.

39. The thin film semiconductor device as claimed in claim 21 wherein the amorphous/nanocrystalline semiconductor ionic metal oxide is characterized by an energy gap less than approximately 4 eV when present in pure XO form and the amorphous/nanocrystalline insulating covalent metal oxide is characterized by an energy gap greater than approximately 6 eV when presents in pure YO form.

40. The thin film semiconductor device as claimed in claim 21 comprises a second gate metal electrode over the passivation layer and overlaying the channel area.

41. A stable thin film semiconductor device with a stable metal-oxide channel layer comprising:
a substrate with dielectric top surface;
a gate metal layer patterned to a pre-determined pattern including a gate electrode area;
a gate dielectric layer overlying the gate electrode area;
a stable metal-oxide semiconductor active layer overlying at least the gate electrode area;
source and a drain terminals overlying and contacting a top surface of the stable metal-oxide semiconductor active layer everywhere except the top surface of a conductive channel between the source and drain terminals;
a first passivation layer overlying the conductive channel and at least part of the source and drain terminals;
an optional second passivation layer with hydrophobic surface property overlying the first passivation layer;
the stable metal oxide semiconductor active layer including a composite/blend/mixture of an amorphous/nanocrystalline insulating covalent metal oxide material and an amorphous/nanocrystalline semiconductor ionic metal oxide material, and
the composite/blend/mixture of the amorphous/nanocrystalline insulating covalent metal oxide material and the amorphous/nanocrystalline semiconductor ionic metal oxide material having a carrier concentration determined by one of oxygen and/or nitrogen being included during the deposition and/or during post-fabrication annealing.

42. A thin film semiconductor device comprising:
a semiconductor layer;
a pair of electrodes positioned in communication with the semiconductor layer and defining a conductive channel in the semiconductor layer;
a gate electrode in communication with the conductive channel and positioned to control conduction of the channel;
the semiconductor layer including an amorphous/nanocrystalline insulating covalent metal oxide material including one of aluminum oxide, silicon oxide, magnesium oxide, beryllium oxide, boron oxide, or combinations thereof and an amorphous/nanocrystalline semiconductor ionic metal oxide material including one of zinc oxide, indium oxide, tin oxide, gallium oxide, cadmium oxide, tantalum oxide, titanium oxide, tungsten oxide, molybdenum oxide, vanadium oxide, niobium oxide, or combinations thereof, the
amorphous/nanocrystalline insulating covalent metal oxide material and the amorphous/nanocrystalline semiconductor ionic metal oxide material being mixed in a predetermined ratio that forms a continuous network of the amorphous/nanocrystalline semiconductor ionic metal oxide material and prevents the amorphous/nanocrystalline semiconductor ionic metal oxide material from becoming poly crystalline at processing temperatures;
the composite/blend/mixture of the amorphous/nanocrystalline insulating covalent metal oxide material and the amorphous/nanocrystalline semiconductor ionic metal oxide material being deposited on a supporting structure; and
the composite/blend/mixture of the amorphous/nanocrystalline insulating covalent metal oxide material and the amorphous/nanocrystalline semiconductor ionic metal oxide material having a carrier concentration determined by one of oxygen and nitrogen being included during the deposition and/or during post-fabrication annealing.

43. The thin film semiconductor device as claimed in claim wherein the composite/blend/mixture is deposited in an orientation supported by a substrate in one of a top gate bottom pair of electrodes; top gate top pair of electrodes; bottom gate bottom pair of electrodes; and bottom gate top pair of electrodes configuration.

44. The thin film semiconductor device as claimed in claim 42 wherein the amorphous/nanocrystalline semiconductor ionic metal oxide is characterized by an energy gap less than approximately 4 eV and the amorphous/nanocrystalline insulating covalent metal oxide is characterized by an energy gap greater than approximately 6 eV.

45. The thin film semiconductor device as claimed in claim 42 wherein the composite/blend/mixture is represented by the formula XOₐYO_{b}, where YO is an amorphous/nanocrystalline insulating covalent metal oxide and XO is an amorphous semiconductor ionic metal oxide and where ‘a’ is the amount of amorphous/nanocrystalline semiconductor ionic metal oxide in the composite/blend/mixture and ‘b’ is the amount of amorphous insulating covalent metal oxide in the composite mixture and where ‘a’ and ‘b’ are >0.

46. The thin film semiconductor device as claimed in claim 45 wherein the composite/blend/mixture metal-oxide channel layer has a gradient or step composition change with the amount of YO higher in the vicinity of channel-passivation interface than in the vicinity of channel-GI interface.

47. The thin film semiconductor device as claimed in claim 45 wherein the composite/blend/mixture metal-oxide channel layer has a gradient or step composition change with the amount of YO in the vicinity of channel-passivation and channel-GI interfaces higher than that in the center of the channel layers.

48. The thin film semiconductor device as claimed in claim 45 wherein the composite/blend/mixture metal-oxide channel layer XOₐYO_{b} is in form of [(X1-O)ₐ₁(X2-O)ₐ₂]ₐYO_{b} (a=a1+a2, a+b=1) in which the chemical dissociation energy of X2-O bond is substantially higher than X1-O bond.

49. The thin film semiconductor device as claimed in claim 48 wherein the composite/blend/mixture metal-oxide channel layer [(X1-O)ₐ₁(X2-O)ₐ₂]ₐYO_{b} has different composition along the vertical direction of the channel layer and X2-O in the vicinity of channel-GI interface, or in the vicinity of channel-passivation interface or in both vicinities higher than in the center along the vertical direction.
